(19) United States
(12) Patent Application Publication
(10) Pub. No.: US 2016/0329685 A1
(43) Pub. Date: Nov. 10, 2016

(54) SEMICONDUCTOR LASER DEVICE

(71) Applicant: MITSUBISHI ELECTRIC CORPORATION, Tokyo (JP)

(72) Inventors: Tomotaka KATSURA, Chiyoda-ku (JP); Daiji MORITA, Chiyoda-ku (JP); Susumu KONNO, Chiyoda-ku (JP); Shuichi FUJIKAWA, Chiyoda-ku (JP)

(73) Assignee: MITSUBISHI ELECTRIC CORPORATION, Chiyoda-ku, Tokyo (JP)

(21) Appl. No.: 15/109,353

(22) PCT Filed: Dec. 4, 2014
(86) PCT No.: PCT/JP2014/082084

§ 371 Date: Jun. 30, 2016

(30) Foreign Application Priority Data
Jan. 14, 2014 (JP) 2014-004078

(51) Int. Cl. H01S 5/40; G01J 1/42; H01S 5/14

(52) U.S. Cl. CPC H01S 5/4012; H01S 5/14; H01S 5/4087; G01J 1/4257

(57) ABSTRACT

A semiconductor laser device including an external resonator including: emitters of a semiconductor laser which output a plurality of beams having different wavelengths; a combining optical system which spatially overlaps the plurality of beams output from the semiconductor laser; a wavelength dispersive element which overlaps the overlapped plurality of beams into a single beam by wavelength dispersion; and a partial reflecting mirror which reflects a portion of the single beam and returns same to the wavelength dispersive element, wherein when the width of the wavelength dispersive element in a direction in which the single beam is separated into a plurality of beams by wavelength dispersion is taken as a wavelength dispersive element width, and when the beam upon establishment of normal oscillation is taken as a normal oscillation beam, the wavelength dispersive element width is the same size as the width of the normal oscillation beam.

### TECHNICAL FIELD

This invention relates to a semiconductor laser device in which rays from a plurality of emitters are wavelength-overlapped by an optical element having wavelength dispersing properties, in an external resonator configuration.

### BACKGROUND ART

In a conventional semiconductor laser device, a spatial filter is inserted between a wavelength dispersive element and a partial reflecting mirror of an external resonator, in order to suppress oscillation due to an external resonator light path established between different emitters (this is called “cross-coupling” below) (See, for example, PTL1 and PTL2).

### CITATION LIST

### Patent Literature

### [PTL1]

U.S. patent Ser. No. 06/192,062

### [PTL2]

### U.S. Patent Application Publication No. 2013/0208361

### [PTL3]

### WO 2014/087726

### SUMMARY OF INVENTION

### Technical Problem

However, the prior art involves the following problems.

In the semiconductor laser device of PTL 1, there is a problem of decrease in the laser power and light condensing properties, due to aberration and/or loss in the lenses used for the spatial filter. Furthermore, if a spatial filter without lenses (a slit, etc.) is used, then it is difficult to separate the required normal oscillation from the cross-coupling. As a result of this, there is a problem in that either the suppression of cross-coupling is insufficient, or the normal oscillation is also suppressed.

This invention was devised in order to solve the problems described above, an object thereof being to provide a semiconductor laser device whereby cross-coupling oscillation can be suppressed efficiently without reduction of the laser power or the light condensing properties, and without requiring additional installation of an optical element such as a spatial filter in the external resonator.

### Solution to Problem

The semiconductor laser device according to this invention is a semiconductor laser device including an external resonator configured by being provided with: a semiconductor laser which outputs a plurality of beams having different wavelengths; a combining optical system which spatially overlaps the plurality of beams output from the semiconductor laser; a wavelength dispersive element which overlaps the overlapped plurality of beams into a single beam by wavelength dispersion; and a partial reflecting mirror which reflects a portion of the single beam and returns same to the wavelength dispersive element, wherein when the width of the wavelength dispersive element in a direction in which the single beam is separated into a plurality of beams by wavelength dispersion is taken as a wavelength dispersive element width, and when the beam upon establishment of normal oscillation is taken as a normal oscillation beam, the wavelength dispersive element width is the same size as the width of the normal oscillation beam.

### Advantageous Effects of Invention

According to this invention, by making the width of the wavelength dispersive element, where there is the greatest spatial separation between the optical path of normal oscillation and the optical path of cross-coupling, the same size as the width of the normal oscillation beam, the cross-coupling oscillation beam is removed from the normal oscillation beam. As a result of this, it is possible to obtain a semiconductor laser device which is capable of suppressing cross-coupling oscillation efficiently, without decline in the laser power or light condensing properties, and without newly adding optical elements, such as a spatial filter, to the external resonator.

### BRIEF DESCRIPTION OF DRAWINGS

FIG. 1 is a first schematic drawing showing an example of a semiconductor laser device according to a first embodiment of the present invention.

FIG. 2 is a first schematic drawing showing an example of a semiconductor laser device according to the first embodiment of the present invention.

FIG. 3 shows a wavelength spectrum during normal oscillation according to the first embodiment of the present invention.

FIG. 4 is a schematic drawing for describing cross-coupling oscillation according to the first embodiment of the present invention.

FIG. 5 shows a wavelength spectrum when cross-coupling oscillation occurs, in the first embodiment of the present invention.

FIG. 6 shows a graph of the intensity distribution of a normal oscillation beam on the wavelength dispersive element according to the first embodiment.

FIG. 7 is a schematic drawing showing a semiconductor laser device relating to a second embodiment of the present invention.

FIG. 8 is a schematic drawing showing a semiconductor laser device relating to a third embodiment of the present invention.

### DESCRIPTION OF EMBODIMENTS

Below, a preferred embodiment of a semiconductor laser device according to this invention is described with reference to the drawings. Parts which are the same or equivalent in the drawings are labelled with the same reference numerals.

### First Embodiment

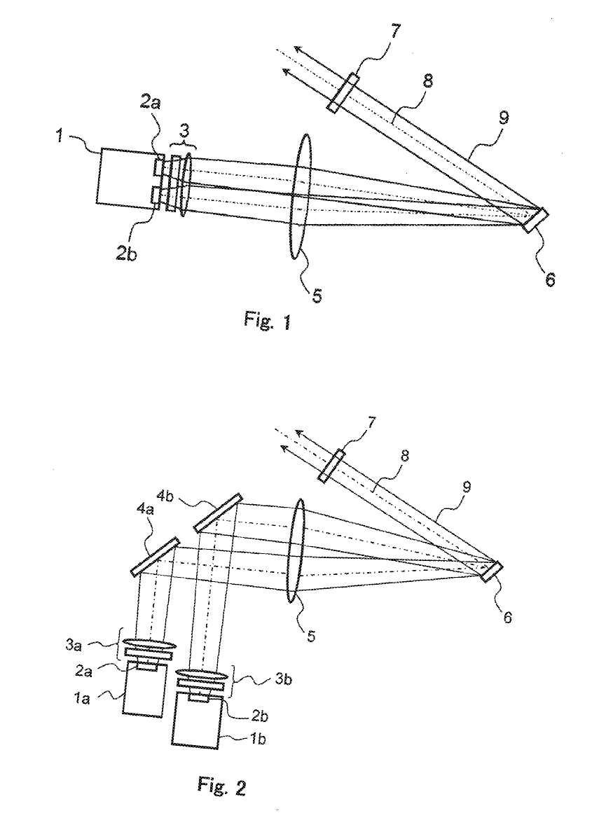

FIG. 1 and FIG. 2 are schematic drawings showing an example of a semiconductor laser device according to a first embodiment of the present invention. More specifically, FIG. 1 shows a configuration wherein light from the emitters 2a, 2b of one semiconductor laser 1 is overlapped into a single beam, by using the wavelength dispersion of a wavelength dispersive element 6. Furthermore, FIG. 2 shows a configuration wherein light from the emitters 2a, 2b of a plurality of semiconductor lasers 1a, 1b is overlapped into a single beam, by using the wavelength dispersion of a wavelength dispersive element 6.

In FIG. 1, a laser resonator is configured by being provided with a light exit side surface of the semiconductor laser 1 on the side where the emitters 2a, 2b emit light, the opposite surface of the semiconductor laser 1, and a partial reflecting mirror 7. In the semiconductor laser 1, the emitters 2a, 2b are normally themselves resonators, apart from the resonator described above, and therefore the resonator configured by being provided with the partial reflecting mirror 7 and the emitters 2a, 2b is referred to here as an external resonator, in order to distinguish between the two types of resonator.

For the sake of simplicity, FIG. 1 shows an example of one semiconductor laser 1 which has two emitters 2a, 2b. However, the semiconductor laser device of the first embodiment is not limited to this configuration. For example, there may be two or more semiconductor lasers 1.

Furthermore, apart from the case where a semiconductor laser bar having a plurality of emitters 2 is used as the semiconductor laser 1, as shown in FIG. 2, it is also possible to overlap the light from a plurality of emitters 2a, 2b into a single beam as described below, similarly to the case of a so-called “single-emitter” semiconductor laser in which respective semiconductor lasers 1a and 1b each have one emitter 2a, 2b. This is described below on the basis of FIG. 2.

In FIG. 2, in practice, the beam reciprocates inside the external resonator, but first, the propagation of the beam in a direction from the emitters 2a, 2b towards the partial reflecting mirror 7 will be described.

The beams generated from the emitters 2a, 2b of the semiconductor lasers 1a, 1b are emitted in a dispersed fashion. Beam parallelization optical systems 3a, 3b make the beams generated by the semiconductor lasers 1a, 1b substantially parallel, in order to couple with the mode of the external resonator.

For the beam parallelization optical systems 3a, 3b, it is possible to use a cylindrical lens, a spherical lens, an aspherical lens, a curved mirror, or a combination of these. In general, the angle of dispersion of the light generated from the semiconductor lasers 1a, 1b is anisotropic and the angle of dispersion differs between the direction perpendicular to the plane of the drawings and the direction in the plane of the drawings. Therefore, it is desirable to use a combination of a plurality of lenses or curved mirrors, for the beam parallelization optical systems 3a, 3b.

The two beams which have been made substantially parallel by the beam parallelization optical systems 3a, 3b are redirected towards a combining optical system 5 by mirrors 4a, 4b. In FIG. 2, the beam is redirected by using mirrors 4a and 4b, but a case which does not use mirrors is also possible, as shown in FIG. 1.

The two beams from the emitters 2a, 2b are overlapped spatially on the wavelength dispersive element 6 by the combining optical system 5. FIG. 2 shows an example where the combining optical system 5 is configured by being provided with a single lens, but the combining optical system 5 may also be configured by being provided with a cylindrical lens, a spherical lens, an aspherical lens, a curved mirror, or a combination of these, and the arrangement of the beam parallelization optical system 3 may also be modified so as to serve as a combining optical system 5 (see, for example, PTL 3).

The wavelength dispersive element 6 may use a reflective diffracting grating, a transmissive diffraction grating, a prism, or an element combining a diffraction grating and a prism (known as a “grism”). The greater the wavelength dispersion of the wavelength dispersive element 6, in other words, the greater the difference in the diffraction angle or refraction angle when beams of different wavelengths are input, the smaller the space in which the beams from the plurality of semiconductor lasers 1a, 1b can be overlapped. Therefore, it is more desirable to use a diffraction grating than a prism.

If the light beams from the different emitters 2a, 2b have certain specific different wavelengths, then the plurality of input beams are overlapped into a single beam by the wavelength dispersion properties of the wavelength dispersive element 6, in other words, properties whereby the diffraction angle or refraction angle varies depending on the wavelength.

The beams which have been overlapped into a single beam are output towards the partial reflecting mirror 7. A portion of the beam irradiated onto the partial reflecting mirror 7 is transmitted and extracted as laser power, and the remaining portion thereof is reflected. The reflected beam propagates in the opposite direction along the same path as the beam from the emitters 2a, 2b towards the partial reflecting mirror 7. When the reflected beam is incident on the emitters 2a, 2b of the semiconductor lasers 1a, 1b, and returns as far as the end face behind the emitters 2a, 2b of the semiconductor lasers 1a, 1b, then an external resonator is established. In order to establish an external resonator of this kind, it is necessary to suitably adjust the positions and angles of the partial reflecting mirror 7, the wavelength dispersive element 6, the combining optical system 5, the mirrors 4a, 4b, and the beam parallelization optical systems 3a, 3b.

When this external resonator has been established, a single optical axis is established between the partial reflecting mirror 7 and the wavelength dispersive element 6, whereas between the wavelength dispersive element 6 and the emitters 2a, 2b, there are two different optical axes: one linking the wavelength dispersive element 6 and the emitter 2a and one linking the wavelength dispersive element 6 and the emitter 2b. The laser oscillation wavelengths of the emitters 2a, 2b are automatically determined in order to establish these optical axes.

In other words, the oscillation wavelengths of the emitters 2a, 2b are automatically determined in such a manner that the external resonator, when established, is established on the optical axis indicated as the normal oscillation optical axis 8 in FIG. 2, these oscillation wavelengths being respectively different wavelengths. This oscillation is called “normal oscillation” below.

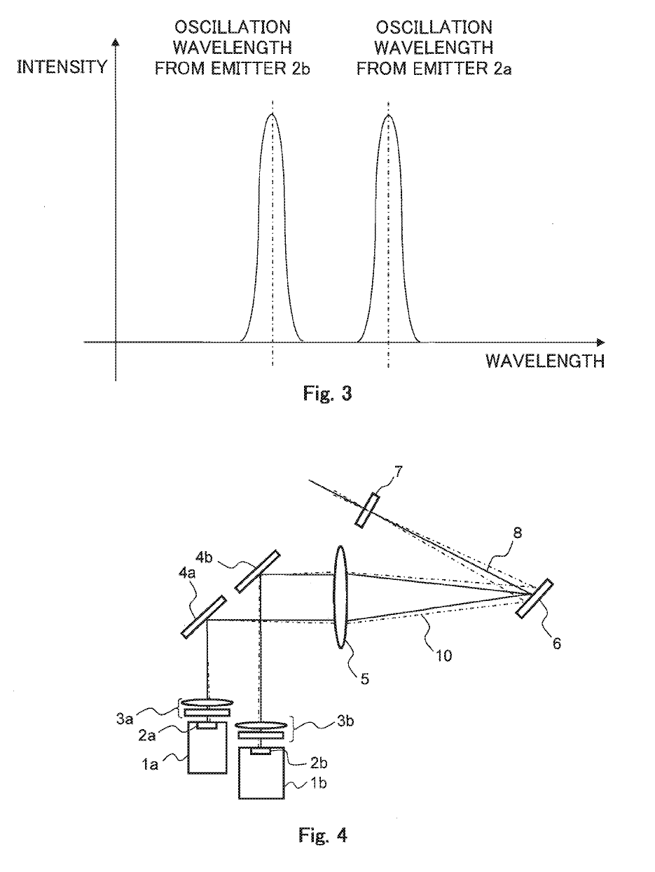

FIG. 3 shows the wavelength spectrum during normal oscillation relating to a first embodiment of the present invention. In this normal oscillation, two beams from the emitters 2a, 2b are overlapped and output from the partial reflecting mirror 7 as a single beam. As a result of this, it is possible to multiply the brightness of the beam by approximately two times. When the number of semiconductor lasers 1a, 1b and emitters 2a, 2b is increased, then it is possible to increase the brightness of the beam yet further.

On the other hand, undesirable laser oscillation may occur, even if each of the optical elements in the external resonator is adjusted so as to establish the normal oscillation shown in FIG. 2. As described below, undesirable laser oscillation of this kind is called “cross-coupling” oscillation, due to occurring as a result of coupling between different emitters 2a, 2b.

FIG. 4 is a schematic drawing for describing cross-coupling oscillation according to the first embodiment of the present invention. Cross-coupling oscillation is described here with reference to FIG. 4. In FIG. 4, the optical axis of the cross-coupling oscillation is indicated by the dotted-line cross-coupling optical axis 10. Furthermore, the optical axis of normal oscillation is indicated by the solid-line normal oscillation optical axis 8.

The normal oscillation optical axis 8 is situated at one point on the wavelength dispersive element 6 and is incident perpendicularly on the partial reflecting mirror 7. On the other hand, the cross-coupling optical axis 10 is not gathered at one point on the wavelength dispersive element 6, and is incident obliquely, rather than perpendicularly, on the partial reflecting mirror 7.

The cross-coupling optical axis 10 is incident obliquely on the emitters 2a, 2b, but since beams can be generated with a certain angular range from the emitters 2a, 2b, then an external resonator is also established on this obliquely incident cross-coupling optical axis 10.

In this case, a portion of the beam output from the emitter 2b is reflected by the partial reflecting mirror 7 and is incident on the emitter 2b. Furthermore, a portion of the beam output from the emitter 2a is reflected by the partial reflecting mirror 7 and is incident on the emitter 2a. In this way, an external resonator is established on a light path in which the beams are respectively input and output between the two emitters 2a and 2b.

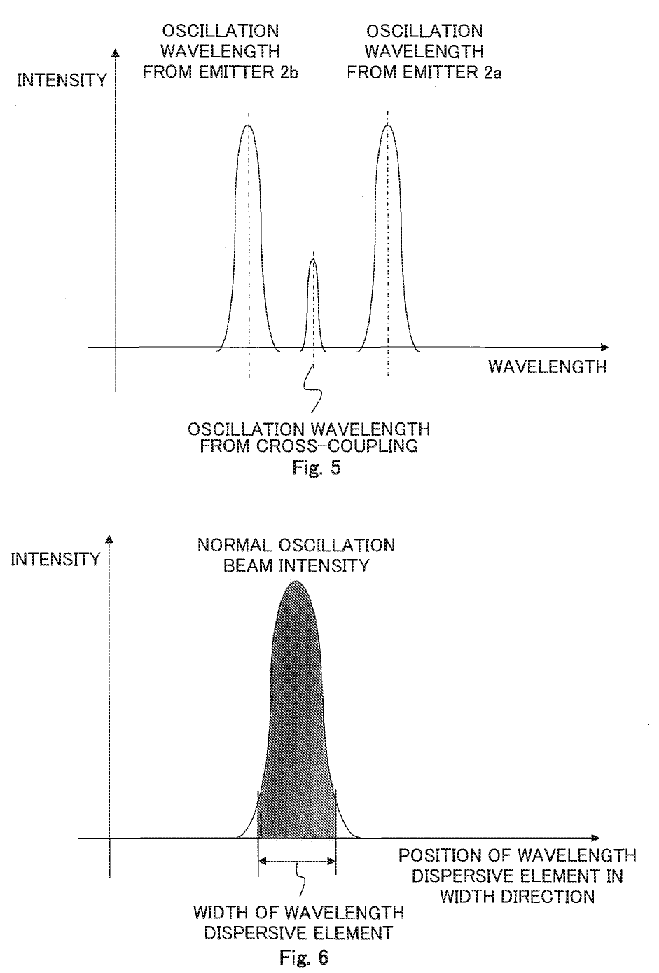

FIG. 5 shows the wavelength spectrum when cross-coupling oscillation occurs, in a first embodiment of the present invention. As shown in FIG. 5, the oscillation wavelength of the cross-coupling oscillation is an intermediate wavelength between the oscillation wavelengths of the emitter 2a and the emitter 2b in normal oscillation.

Furthermore, as shown in FIG. 4, the normal oscillation optical axis 8 is a single optical axis which is incident perpendicularly on the partial reflecting mirror 7, whereas the cross-coupling optical axis 10 is oblique at the partial reflecting mirror 7. In this way, due to the mixing of the cross-coupling oscillation beam which has a different direction of travel, there is a decline in the light condensing properties of the beam generated from the external resonator.

In the external resonator, the occurrence of cross-coupling is identifies by observing the wavelength spectrum of the external resonator power. If there is no cross-coupling and only normal oscillation occurs, then the number of peaks in the wavelength spectrum matches the number of emitters 2 included in the external resonator.

Therefore, in the semiconductor laser device according to the first embodiment, in order to suppress cross-coupling oscillation, the width of the wavelength dispersive element 6 is set so as to be equal to the width of the normal oscillation beam 9 on the wavelength dispersive element 6, as shown in FIG. 1 and FIG. 2.

Here, the width of the wavelength dispersive element 6 means the size, in the long-edge direction, of the wavelength dispersive element 6 which is represented as a rectangle in FIG. 1 and FIG. 2. In other words, this is the width of the wavelength dispersive element 6 in the direction in which the single beam is separated into two beams by wavelength dispersion. Stated alternatively, this is the width of the light-receiving surface of the wavelength dispersive element 6 in the plane having wavelength dispersion properties (the plane of the drawings in FIG. 1 and FIG. 2). The size in the direction perpendicular to the plane of the drawings should be a size sufficient to receive the normal oscillation beam 9, and even if this size is too large, there is no adverse effect on the operation of the external resonator.

FIG. 6 shows a graph of the intensity distribution of the normal oscillation beam 9 on the wavelength dispersive element 6 in the first embodiment of the present invention. The horizontal axis in FIG. 6 indicates the position of the wavelength dispersive element 6 in the width direction. The intensity distribution of the normal oscillation on the wavelength dispersive element 6 is a bell shape close to a Gaussian shape, with a strong intensity in the center, as shown in FIG. 6.

In FIG. 6, the portion of the beam intensity of the normal oscillation which is irradiated onto the wavelength dispersive element 6 is indicated by coloring (gray). As a general measure, the width of the wavelength dispersive element 6 is set in such a manner that the power irradiated onto the wavelength dispersive element 6 as indicated by the coloring is no less than 95%, and desirably no less than 99%, of the total power of the beam of the nominal oscillation. If the wavelength dispersive element 6 is smaller than this, then the loss relating to normal oscillation increases and there is marked decline in the laser power produced by the external resonator.

On the other hand, if the wavelength dispersive element 6 is too large, then the cross-coupling oscillation beam can also be received sufficiently and diffracted by the wavelength dispersive element 6, which means that cross-coupling oscillation can occur inside the external resonator, and therefore the effect in suppressing cross-coupling oscillation is reduced. In other words, as a general measure, the upper limit of the width of the wavelength dispersive element 6 is 1.1 times the width that includes 99% of the total beam power of normal oscillation. If the width of the wavelength dispersive element 6 is greater than the upper limit, the effect in suppressing cross-coupling oscillation is reduced.

In order to reduce normal oscillation loss, it is necessary for the normal oscillation optical axis 8 to overlap satisfactorily with the wavelength dispersive element 6. If the mirrors 4a, 4b are omitted, then the degree of overlap of the normal oscillation optical axis 8 on the wavelength dispersive element 6 is determined by the installation accuracy of the semiconductor lasers 1a, 1b, and therefore it is difficult to achieve a satisfactory overlap. Consequently, by installing the mirrors 4a, 4b in the resonator and adjusting the position of the beam parallelization optical systems 3a, 3b and the orientation of the mirrors 4a, 4b, it is possible to cause the normal oscillation optical axis 8 to overlap satisfactorily with the wavelength dispersive element 6.

If the semiconductor laser 1 is a single-emitter semiconductor laser or a semiconductor laser bar, then the normal oscillation is a beam close to the diffraction limit. The beam shape of the normal oscillation beam 9 on the wavelength dispersive element 6 can be calculated by using ray tracing and wave calculation.

As shown in FIG. 4, the greatest spatial separation between the cross-coupling optical axis 10 and the normal oscillation optical axis 8 in the external resonator occurs on the wavelength dispersive element 6. Therefore, by selecting the cross-coupling oscillation beam and the normal oscillation beam at the location where they are separated by the greatest amount, it is possible to suppress cross-coupling efficiently, without increasing the normal oscillation loss.

Meanwhile, when a spatial filter is provided inside the external resonator as in the prior art, then the light scattered by the shielding structure (opening or slit) for selectively shutting out the cross-coupling light is returned to the emitters 2a, 2b and is amplified inside the emitters 2a, 2b, thus giving rise to loss. Furthermore, if a lens is employed for the spatial filter, than a lens having large aberration and a short focal distance is required, and therefore deterioration of the beam quality of the normal oscillation and decline in power occur, due to the aberration of the lens which is inserted into the external resonator.

As described above, according to the first embodiment, a configuration is achieved in which the width of the wavelength dispersive element at which there is the greatest spatial dispersion between the optical path of the normal oscillation and the optical path of the cross-coupling is set to the same size as the width of the normal oscillation beam. As a result of this, the cross-coupling oscillation is suppressed effectively and beams from a plurality of emitters can be overlapped, without providing, in the external resonator, an optical element or shielding member which disrupts the external resonance action and gives rise to deterioration of the quality of the normal oscillation beam or decline in the power. Therefore, a marked effect is obtained in that a high-brightness laser power can be obtained.

### Second Embodiment

In the second embodiment, a configuration is described in which a plurality of external resonators share a single partial reflecting mirror 7. By this configuration, it is possible to suppress costs and guide a beam easily into an optical fiber, or the like.

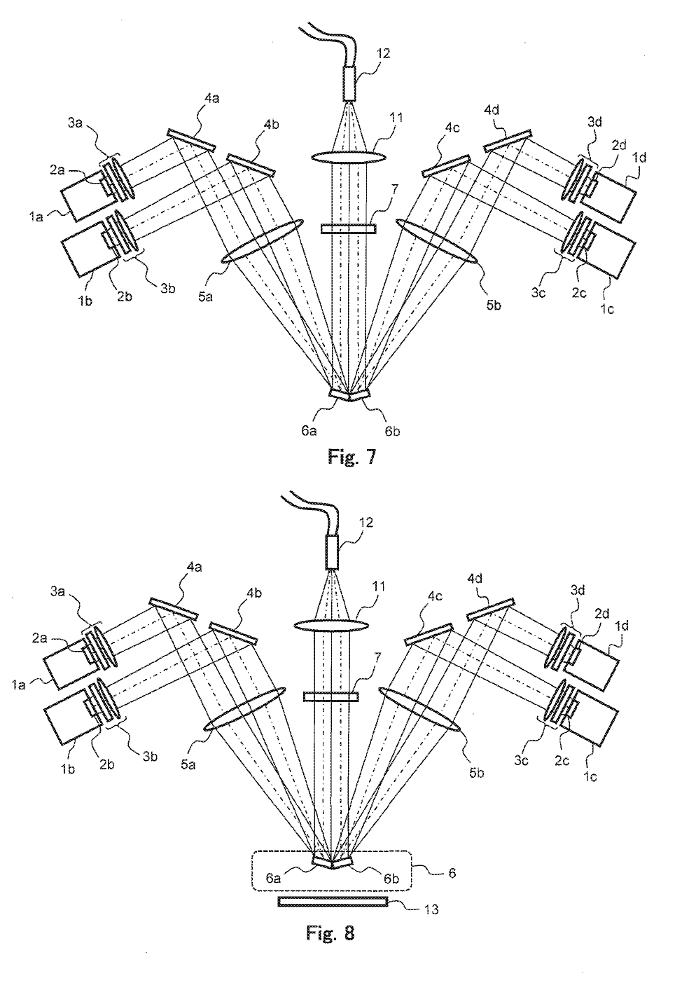

FIG. 7 is a schematic drawing showing a semiconductor laser device relating to a second embodiment of the present invention. The semiconductor laser device of the second embodiment combines two sets of the semiconductor laser devices of the first embodiment, in an adjacent fold-back arrangement.

Here, the semiconductor laser device according to the first embodiment is called a basic module. The functions of the semiconductor lasers 1a, 1b, 1c, 1d, the emitters 2a, 2b, 2c, 2d, the beam parallelization optical systems 3a, 3b, 3c, 3d, the mirrors 4a, 4b, 4c, 4d, the combining optical system 5 and the wavelength dispersive element 6 shown in FIG. 7 are the same as the first embodiment.

In FIG. 7, two basic modules are arranged in mirror symmetry. Here, the semiconductor laser devices each have optical elements of the same number as in the first embodiment, but the partial reflecting mirror 7 which constitutes one end of the external resonator is shared by two basic modules. The number of basic modules may be three or more.

Furthermore, in the second embodiment, similarly to the first embodiment, the width of the wavelength dispersive element 6 is set to substantially the same size as the width of the normal oscillation beam 9 on the wavelength dispersive element 6. Therefore, as shown in FIG. 7, it is possible to arrange the two basic modules in an adjacent configuration. As a result of this, it is possible to virtually eliminate any gap between the beam generated from the left hand-side basic module and the beam generated from the right hand-side basic module.

When a semiconductor laser device is used for laser processing, the beam is often input into an optical fiber and directed to the vicinity of the object to be processed. Therefore, in the second embodiment, the two beams output from the partial reflecting mirror 7, between which there is no gap, are guided to an optical fiber 12 by using a condensing lens 11.

According to this configuration, although the light condensing properties of the beam are two times worse than that of a basic module, the power is two times greater. In other words, it is possible to output twice the power, without any change in brightness. On the other hand, in the prior art, in order to guide beams from a plurality of modules into an optical fiber, apart from the condensing lens, it has also been necessary to provide an optical system including mirrors or lenses, etc. in order to make the beams generated from the basic modules converge.

As described above, according to the second embodiment, two basic modules are installed in mirror symmetry and share a single partial reflecting mirror. As a result of this, it is possible to share the partial reflecting mirror between two basic modules, as well as being able to guide the light into a single optical fiber, without adding a new optical system for causing the beams from the two basic modules to converge. Furthermore, marked beneficial effects are obtained by reducing the optical elements, in that the manufacturing costs of the semiconductor laser are reduced, stability is improved, and efficiency is also improved.

### Third Embodiment

The third embodiment describes a configuration in which the state of the external resonator is monitored by detecting the power of the beam, from the normal oscillation beam 9, which leaks to the rear of the wavelength dispersive element 6 due to being irradiated outside the width of the wavelength dispersive element 6.

FIG. 8 is a schematic drawing showing a semiconductor laser device relating to the third embodiment of the present invention. The semiconductor laser device of the third embodiment shown in FIG. 8 differs from that of the second embodiment in FIG. 7 in being further provided with a beam sensor 13 to the rear of the wavelength dispersive element 6. The remainder of the configuration is the same as FIG. 7.

The width of the wavelength dispersive element 6 of the third embodiment shown in FIG. 8 is set in such a manner that that no less than 95.0% and no more than 99.5% of the total power of the normal oscillation beam 9 is irradiated within the width of the wavelength dispersive element 6. In other words, power of between 0.5% and 5.0% of the power of the normal oscillation beam 9 is irradiated outside the width of the wavelength dispersive element 6 and leaks to the rear of the wavelength dispersive element 6. In the third embodiment, by using a beam sensor 13 provided to the rear of the wavelength dispersive element 6 to detect the value of this leaked power of the normal oscillation beam 9, the state of the external resonator is monitored, in other words, whether the external resonator is generating normal power.

For the beam sensor 13, it is possible to use a single photodiode, a photodiode array, a CCD (Charged Coupled Device) image sensor, or a CMOS (Complementary Metal Oxide Semiconductor) image sensor. If using a single photodiode, it is possible to detect only decline in the power of the external resonator. Furthermore, if the spatial distribution is detected by using a photodiode array, CCD image sensor or CMOS image sensor, then it is possible to detect which semiconductor laser 1, of the plurality of semiconductor lasers 1a, 1b, 1c, 1d, has a decline in power.

When a semiconductor laser device is used as a laser processing device, it is necessary to monitor the laser power in order to keep the processing quality uniform, and according to the configuration of the third embodiment, as well as being able to monitor the laser power in the external resonator, it is also possible readily to identify the cause and resolve the problem, if there is a decline in laser power.

More specifically, when the laser power declines after the light has been guided to the optical fiber 12, for example, then a monitoring unit (not illustrated) of the semiconductor laser device is able to identify whether the optical fiber 12 is damaged, or whether the laser power in the external resonator has declined, by comparing the laser power in the external resonator as detected by the beam sensor 13 with the power after the light is guided to the optical fiber 12.

Moreover, if there has been a decline in the laser power of the external resonator, then as stated above, by detecting the spatial distribution of the power of the beam detected by the beam sensor 13, it is possible also to identify which of the semiconductor lasers 1a, 1b, 1c, 1d has a decline in power.

As described above, according to the third embodiment, a beam sensor for detecting the power of the beam, from the normal oscillation beam, leaking to the rear of the wavelength dispersive element due to being irradiated outside the width of the wavelength dispersive element is further provided to the rear of the wavelength dispersive element. As a result of this, since the state of the external resonator is monitored on the basis of the value of the power of the beam irradiated outside the wavelength dispersive element which is detected by the beam sensor, then it is possible to achieve a marked effect in facilitating recovery when there is a decline in laser power.

FIG. 8 shows an example in which a beam sensor 13 is further provided in the configuration of the second embodiment shown in FIG. 7, but the third embodiment is not limited to this configuration. For example, similar beneficial effects can also be obtained by a configuration in which the beam sensor 13 is further provided in the configuration of the first embodiment shown in FIG. 1 and FIG. 2.

1. A semiconductor laser device, comprising an external resonator configured by being provided with: a semiconductor laser which outputs a plurality of beams having different wavelengths; a combining optical system which spatially overlaps the plurality of beams output from the semiconductor laser; a wavelength dispersive element which overlaps the overlapped plurality of beams into a single beam by wavelength dispersion; and a partial reflecting mirror which reflects a portion of the single beam and returns same to the wavelength dispersive element,
wherein when the width of the wavelength dispersive element in the beam overlapping direction in which the single beam is separated into a plurality of beams by wavelength dispersion is taken as a wavelength dispersive element width, and when the beam upon establishment of normal oscillation is taken as a normal oscillation beam, the wavelength dispersive element width is the same size as the width of the normal oscillation beam.

2. The semiconductor laser device according to claim 1, wherein a plurality of the external resonators share the single partial reflecting mirror.

3. The semiconductor laser device according to claim 1, wherein the wavelength dispersive element width is set in such a manner that the power of the beam irradiated onto the wavelength dispersive element is no less than 95% of the total power of the normal oscillation beam.

4. The semiconductor laser device according to claim 1,
wherein the wavelength dispersive element width is set in such a manner that the power of the beam irradiated onto the wavelength dispersive element is no less than 95.0% and no more than 99.5% of the total power of the normal oscillation beam,
the semiconductor laser device further comprising: a beam sensor which is provided to the rear of the wavelength dispersive element and detects the power of the beam, from the normal oscillation beam, which is irradiated outside the wavelength dispersive element width and leaks to the rear of the wavelength dispersive element; and
a monitoring unit which monitors the state of the external resonator on the basis of a power value of the beam irradiated outside the wavelength dispersive element width as detected by the beam sensor.

5. The semiconductor laser device according to claim 2, wherein the wavelength dispersive element width is set in such a manner that the power of the beam irradiated onto the wavelength dispersive element is no less than 95% of the total power of the normal oscillation beam.

6. The semiconductor laser device according to claim 2,
wherein the wavelength dispersive element width is set in such a manner that the power of the beam irradiated onto the wavelength dispersive element is no less than 95.0% and no more than 99.5% of the total power of the nominal oscillation beam,
the semiconductor laser device further comprising: a beam sensor which is provided to the rear of the wavelength dispersive element and detects the power of the beam, from the normal oscillation beam, which is irradiated outside the wavelength dispersive element width and leaks to the rear of the wavelength dispersive element; and
a monitoring unit which monitors the state of the external resonator on the basis of a power value of the beam irradiated outside the wavelength dispersive element width as detected by the beam sensor.
